(19) United States
(12) Patent Application Publication
(10) Pub. No.: US 2010/0006539 A1
(43) Pub. Date: Jan. 14, 2010

(54) APPARATUS FOR MANUFACTURING SEMICONDUCTOR

(75) Inventors: Cheol Hoon YANG, Gyeonggi-do (KR); Kyu Jin CHOI, Gyeonggi-do (KR); Yong Han JEON, Gyeonggi-do (KR); Euy Kyu LEE, Gyeonggi-do (KR); Tae Wan LEE, Gyeonggi-do (KR)

Correspondence Address: HOSOON LEE, 9600 SW OAK ST. SUITE 525, TIGARD, OR, 97223, US

(73) Assignee: JUSUNG ENGINEERING CO., LTD, Gyeonggi-do (KR)

(21) Appl. No.: 12/259,257

(22) Filed: Oct. 27, 2008

(30) Foreign Application Priority Data
Jul. 8, 2008 (KR) 10-2008-0066151

(51) Int. Cl. H01L 21/3065; C23C 16/00

(52) U.S. Cl. 216/37; 118/723 R; 156/345.37; 118/723 I; 427/569

(57) ABSTRACT

A semiconductor device manufacturing apparatus includes a chamber including a reaction space, a substrate disposing unit configured to dispose a substrate within the chamber, a first heating unit configured to optically heat the reaction space and disposed under the chamber, a second heating unit configured to heat the reaction space through resistive heating and disposed over the chamber, and a plasma generating unit configured to generate plasma in the reaction space. Since the apparatus generates the plasma using the plasma generating unit disposed over the chamber, the deposition process based on heating and the etch process based on the plasma can be simultaneously performed in one single chamber.

### CROSS REFERENCE TO RELATED APPLICATION

This application claims priority to Korean Patent application No. 10-2008-0066151, filed on Jul. 8, 2008 and all the benefits accruing therefrom under 35 U.S.C. 119, the contents of which are herein incorporated by reference in their entirety.

### BACKGROUND OF THE INVENTION

1. Field of the Invention

The present invention relates to an apparatus for manufacturing a semiconductor device, and more particularly to a semiconductor device manufacturing apparatus capable of simultaneously performing etching and deposition processes using a plurality of energy sources that independently operate of each other.

2. Description of the Related Art

In general, a process of manufacturing a semiconductor device is performed in a high temperature greater than approximately 700° C. A process temperature works as a very important factor in a process of manufacturing the semiconductor device. Specially, a temperature in a process of growing a semiconductor thin film becomes a component of adjusting a growth thickness of the thin film as well as growth characteristics of the thin film.

In a conventional semiconductor device manufacturing apparatus, there is disposed a hot wire within a substrate disposing unit where a substrate is disposed, wherein the hot wire acts as a heat source. Then, the substrate disposing unit is heated up to a high temperature and thus the substrate is heated through an upper portion of the substrate disposing unit. The thin film is grown on the substrate by supplying a process gas onto a surface of the heated substrate. However, in this case, it is difficult to uniformly heat the substrate. When supplying the process gas into a chamber, an inner temperature of the chamber is locally changed by the process gas having a low temperature and the temperature variation in the chamber makes a temperature at the surface of the substrate non-uniform. Therefore, recently, there has been introduced a substrate processing apparatus that minimizes the temperature variation by heating a reaction space in the chamber with a heating unit disposed at the outside of the reaction space of the chamber.

However, in case of the conventional semiconductor device manufacturing apparatus for growing the semiconductor thin film, since the thin film is formed on the surface of the substrate loaded into the chamber, foreign substances have to be removed from the surface of the substrate before forming the thin film. Therefore, the foreign substances on the surface of the substrate are removed using a separate cleaning apparatus and then the cleaned substrate is transferred into the chamber to thereby form the thin film. But, during transferring the cleaned substrate from the cleaning apparatus into the chamber, a shallow native oxide layer is formed on the surface of the substrate and thus the quality of the thin film formed on the substrate is deteriorated by the native oxide layer.

To remove the native oxide layer, the conventional semiconductor device manufacturing apparatus employs a method of burning the native oxide layer on the substrate by increasing a heating temperature within the chamber. As a result, the substrate is thermally damaged.

### SUMMARY OF THE INVENTION

To overcome the above drawbacks, the present invention provides a semiconductor device manufacturing apparatus which forms a thin film by removing a native oxide layer on a surface of a substrate using plasma and uniformly heating a reaction space in a chamber using heating sources disposed over and under the chamber, so that it is possible to form the thin film having good quality on the substrate, to minimize thermal damage of the substrate, and to minimize thermal or electrical interference between a plasma generating unit and a heating unit.

In accordance with an aspect of the present invention, there is provided an apparatus for manufacturing a semiconductor device including: a chamber including a reaction space; a substrate disposing unit configured to dispose a substrate within the chamber; a first heating unit configured to optically heat the reaction space and disposed under the chamber; a second heating unit configured to heat the reaction space through resistive heating and disposed over the chamber; and a plasma generating unit configured to generate plasma in the reaction space.

The first heating unit may include a lamp heater and the second heating unit includes a hot wire.

The first heating unit may further include a power supply sector configured to supply power to the lamp heater and a power supply line electrically connecting the power supply sector and the lamp heater, the second heating unit may further include an inner plate having a reflective coating processed bottom, an outer cover covering the inner plate, and a center plate disposed between the inner plate and the outer cover, wherein the hot wire is disposed between the center plate and the inner plate and a low frequency filter is further disposed between the power supply line and the plasma generating unit.

The chamber may include a chamber body, a light penetrating base plate disposed at a lower portion of the chamber body and a top plate disposed at an upper portion of the chamber body, and the plasma generating unit may include at least one antenna disposed in a region between the second heating unit and the top plate of the chamber and a high frequency power sector configured to provide high frequency power to the antenna, wherein the top plate has a light penetrating part and a light non-penetrating part and the non-penetrating part is formed in a region of the top plate corresponding to the antenna.

The chamber may include a chamber body having an inner space therein or a concave groove caving in from the outside to the inside, a light penetrating base plate disposed at a lower portion of the chamber body and a top plate disposed at an upper portion of the chamber body, and the plasma generating unit may include at least one antenna disposed in the inner space or the concave groove and a high frequency power sector configured to provide high frequency power to the antenna.

In accordance with another aspect of the present invention, there is provided a method of manufacturing a semiconductor device using a semiconductor device manufacturing apparatus that includes a chamber having a substrate disposing unit on which a substrate is disposed, a first and a second heating unit disposed under and over the chamber, respectively, and a plasma generating unit disposed at an upper portion of the chamber, the method including: heating up a reaction space of the chamber to a first temperature using at least one of the first and the second heating units; cleaning a surface of the substrate using plasma and a cleaning gas; heating up the reaction space of the chamber to a second temperature using the first and the second heating units, wherein the second temperature is higher than the first temperature; depositing a semiconductor film on the substrate using a deposition gas and an etch gas; stopping the supply of the deposition gas and the etch gas and cooling down the chamber; and unloading the substrate to the outside of the chamber.

The first temperature may be a process temperature at which a native oxide layer on the surface of the substrate is removed using the plasma and is in a range of approximately 200° C. to approximately 600° C., and the second temperature may be a process temperature at which the thin film is deposited and is in a range of approximately 300° C. to approximately 1000° C.

Cleaning the surface of the substrate may include: generating the plasma in the reaction space using the plasma generating unit after injecting the cleaning gas to the reaction space of the chamber, or injecting the cleaning gas to the reaction space after generating the plasma in the reaction space; and stopping the generation of the plasma and the injection of the cleaning gas.

The plasma may be generated by supplying high frequency power to an antenna that is disposed over the chamber in the form of wrapping the chamber.

When depositing the semiconductor film on the substrate, the deposition gas for the deposition of the semiconductor film and the etch gas for the etching of the semiconductor film may be alternately supplied to the reaction space of the chamber, or the deposition gas and the etch gas may be simultaneously supplied to the reaction space.

The plasma may be generated in the reaction space using the plasma generating unit during at least one of the deposition gas and the etch gas being supplied.

A temperature of the reaction space of the chamber may be changed by varying a temperature of the first heating unit while fixing a temperature of the second heating unit.

### BRIEF DESCRIPTION OF THE DRAWINGS

The above and other features and advantages of the present invention will become more apparent by describing in detail preferred embodiments thereof with reference to the attached drawings in which:

FIG. 1 illustrates a cross-sectional view of a semiconductor device manufacturing apparatus in accordance with a first embodiment of the present invention;

FIG. 2 illustrates a plan view of a first heating unit in accordance with the first embodiment of the present invention;

FIG. 3 illustrates a cross-sectional view of an upper portion of a chamber in accordance the first embodiment of the present invention;

FIGS. 4A to 6B are cross-sectional views illustrating local parts of the semiconductor device manufacturing apparatus in accordance with modifications of the first embodiment of the present invention;

FIG. 7 illustrates a cross-sectional view of a semiconductor device manufacturing apparatus in accordance with a second embodiment of the present invention; and

FIG. 8 illustrates a cross-sectional view of a semiconductor device manufacturing apparatus in accordance with a third embodiment of the present invention.

### DESCRIPTION OF THE PREFERRED EMBODIMENTS

Preferred embodiments of the invention are described hereafter in detail with reference to accompanying drawings. The present invention, however, is not limited to the embodiments described herein, but may be modified in a variety of ways, and the embodiments is provided only to fully describe the invention and inform those skilled in the art of the aspects of the invention. The same reference numeral indicates the same components in the drawings.

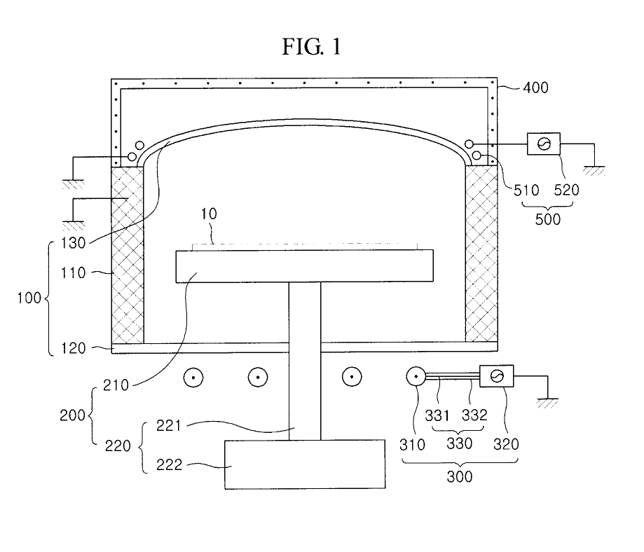

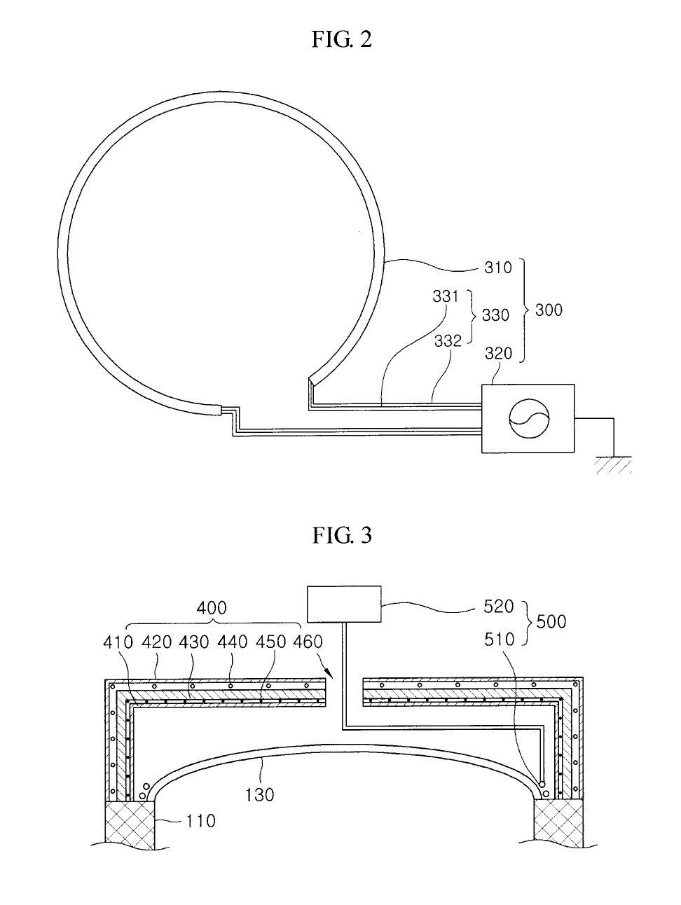

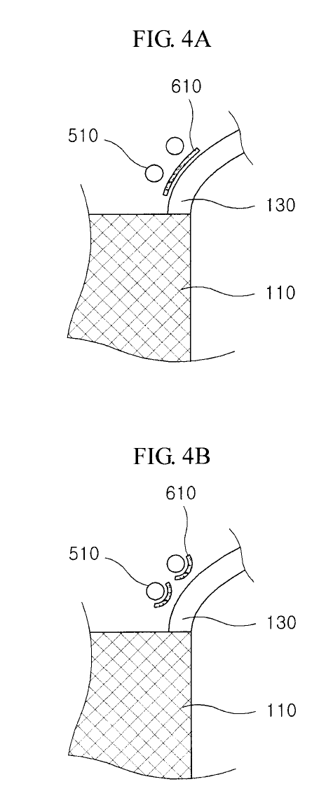

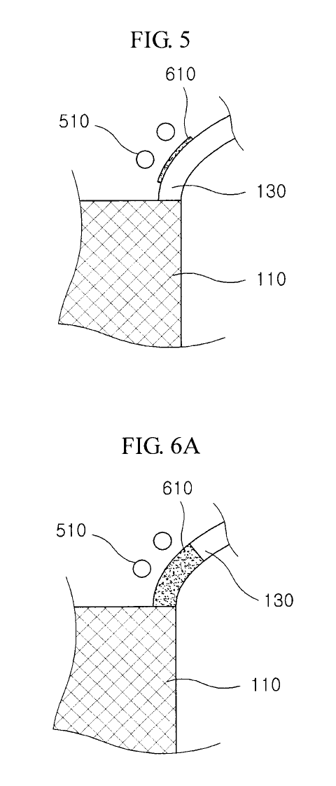

FIG. 1 illustrates a cross-sectional view of a semiconductor device manufacturing apparatus in accordance with a first embodiment of the present invention. FIG. 2 illustrates a plan view of a first heating unit in accordance with the first embodiment of the present invention. FIG. 3 illustrates a cross-sectional view of an upper portion of a chamber in accordance the first embodiment of the present invention. FIGS. 4A to 6B are cross-sectional views illustrating local parts of the semiconductor device manufacturing apparatus in accordance with modifications of the first embodiment of the present invention.

Referring to FIGS. 1 to 3, the semiconductor device manufacturing apparatus in accordance with the first embodiment of the present invention includes a chamber 100 having a reaction space therein, a substrate disposing unit 200 to dispose a substrate 10 in the chamber 100, a first heating unit 300 disposed under the chamber 100 to heat the reaction space, a second heating unit 400 disposed over the chamber 100 to heat the reaction space, and a plasma generating unit 500 to generate plasma in the reaction space.

The chamber 100 includes a chamber body 110 forming an inner space, a base plate 120 and a top plate 130.

The chamber body 110 is fabricated in a cylindrical shape, but it is not limited thereto. The chamber body 110 may be formed in a polygonal shape. A portion or all of the chamber body 110 is preferably formed of a metallic material. In this embodiment, the chamber body 110 is formed using a material such as aluminum or stainless steel. Herein, the chamber body 110 acts as sidewalls of the inner space of the chamber 100. Although it is not shown, given portions of the chamber body 110 may include a substrate gateway through which the substrate gets in and out of the chamber 100, and an end connecting unit of a gas supply apparatus (not shown) for supplying a reaction gas to the reaction space.

The base plate 120 is made with a light penetrating plate. It is effective to allow radiant heat from the outside of the chamber 100 to be transmitted into the reaction space through the base plate 120. Herein, it is effective to make the base plate 120 with quartz. Thus the based plate 120 may act as a window. In another embodiment, only a portion of the base plate 120 is made with a light penetrating plate and the rest of the base plate 120 may be made with a heat conductible, light non-penetrating plate.

The top plate 130 acts as a dielectric plate between the reaction space and an energy source disposed over the chamber 100. In this embodiment, the top plate 130 is formed in a domy shape, but it is not limited thereto. The top plate 130 may be formed in a valve shape. The top plate 130 may be made with a light penetrating plate. That is, the top plate 130 can be made of quartz. Thus, radiant heat transmitted from the reaction space of the chamber 100 toward the top plate 130 penetrates the top plate 130 and the penetrated radiant heat is reflected by a second heating unit disposed over the top plate 130. Then, the reflected radiant heat penetrates the top plate 130 again and is transmitted into the reaction space of the chamber 100. In addition, the top plate 130 may be made of a ceramic material.

Although it is not shown, the chamber 100 may include a pressure adjusting unit, a pressure measuring unit and various units for examining the inside of the chamber 100. Furthermore, a view port may be disposed to look into the reaction space from the outside of the chamber 100.

The substrate 10 is disposed in the reaction space of the chamber 100. Herein, the substrate disposing unit 200 is provided to dispose the substrate 10 in the reaction space.

The substrate disposing unit 200 includes a susceptor 210 on which the substrate 10 is disposed, and a susceptor drive unit 220 to make the susceptor 210 go up and down.

The susceptor 210 is formed in a plate shape that is substantially the same as that of the substrate 10. Also, it is effective to make the susceptor 210 with a material having excellent heat conductivity. It is effective to make the susceptor 210 including at least one substrate disposing region. As a result, at least one substrate 10 can be disposed on the susceptor 210.

The susceptor drive unit 220 includes a driving axle 221 that is connected to the susceptor 210 in the reaction space and extends to the outside of the reaction space, and a driving sector 222 to make the driving axle 221 go up and down to thereby allow the susceptor 210 to go up and down. Herein, the driving axle 221 penetrates the base plate 120 of the chamber 100. For the purpose, the base plate 120 of the chamber 100 may include a penetrating groove. In this embodiment, a stage is used as the driving sector 222. Herein, the stage may include a motor. The susceptor 210 may be rotated by the driving sector 222. Although it is not shown, the substrate disposing unit 200 in accordance with this embodiment may further include a plurality of lift pins to help the loading and unloading of the substrate 10.

In this embodiment, there are disposed the first and the second heating units 300 and 400 under and over the chamber 100, respectively, to heat the reaction space of the chamber 100 and the substrate 10.

That is, by disposing the heat sources over and under the chamber 100, it is possible to minimize heat deviation due to some components, to improve heat uniformity of the inside of the chamber 100 and to uniformly maintain the temperature of the chamber 100 when manufacturing the semiconductor device. Moreover, it is possible to heat and cool the inside of the chamber 100 at high speed and thus to simplify the process of manufacturing the semiconductor device.

The first heating unit 300 is disposed under the chamber 100 to supply heat energy to the chamber 100.

As described above, by disposing the main heating unit at the outside of the chamber 100, i.e., the outside of the reaction space, it is possible to fundamentally prevent metal contamination due to the damage of the heating unit. Meanwhile, the conventional apparatus includes the heating unit disposed within the chamber 100, metal parts such as Mo, Fe or Ni, and heating elements such as SiC or graphite. Therefore, the metal parts of the heating unit are etched by the processing gas, e.g., Cl₂ or HCl, supplied into the chamber, so that the metal contamination occurs. However, if the heating unit is disposed at the outside of the chamber 100 as described in this embodiment, the contamination due to the metal parts can be prevented.

In this embodiment, an optical heat source is used as the first heating unit 300. Thus, the chamber 100 is heated by radiant heat emitted from the optical heat source, i.e., the first heating unit 300. Herein, heating the chamber 100 means heating the reaction space of the chamber 100 and the substrate 10 disposed in the reaction space.

As shown in FIG. 2, the first heating unit 300 includes at least one lamp heater 310, a power supply sector 320 to provide power to the lamp heater 310, and a power supply line 330 electrically connecting the power supply sector 320 and the lamp heater 310.

The lamp heater 310 is disposed beneath the base plate 120 of the chamber 100. The lamp heater 310 may be made in the form of a circular band shape. When using a plurality of lamp heaters, it is effective that the lamp heaters have different diameters from each other and centers consistent with each other, and the consistent centers are consistent with a center of the base plate 120. Of course, the centers of the lamp heaters may be inconsistent with each other. That is, the base plate 120 is divided into a plurality of regions and each of the lamp heaters 310 may be disposed in a corresponding one of the plurality of regions of the base plate 120. Moreover, the lamp heater 310 may be made in a line shape instead of the circular band shape.

In this embodiment, at least one lamp heater 310 is disposed under the base plate 120 that is made with quartz and thus radiant heat from the lamp heater 310 penetrates through the base plate 120 into the reaction space of the chamber 100. As afore-mentioned, only a region of the base plate 120 that is adjacent to the lamp heater 310 may be made with quartz.

The power supply sector 320 supplies power to at least one lamp heater 310. Herein, one power supply sector simultaneously provides power to the plurality of lamp heaters. In another embodiment, a plurality of power supply sectors may independently provide power to the plurality of lamp heaters. Therefore, it is possible to locally adjust the inner temperature of the chamber 100.

In this embodiment, there is provided the power supply line 330 for electrically connecting the power supply sector 320 and the lamp heater 310.

Herein, the power supply line 330 includes a power line 331 and a low frequency filter 332, i.e., a high frequency cut-off filter, covering the power line 331. One end of the power line 331 is connected to the power supply sector 320 and the other end is connected to an electrode terminal of the lamp heater 310.

In this embodiment, it is effective to wrap the power line 331 with the low frequency filter 332 that blocks the current having a high frequency greater than about 100 kHz. This embodiment further includes the plasma generating unit 500. Plasma is generated by supply a high frequency in a range of hundreds of kHz to hundreds of MHz to the plasma generating unit 500. At this time, a problem may occur in the power supplied to the lamp heater 310 through the power line 331 by the high frequency used in generating the plasma. For example, there may be caused problems such as non-uniformity of an amount of current and voltage variation. As a result, radiant energy, i.e., the radiant heat, of the lamp heater 310 may be non-uniform. Therefore, as described above, it is effective to use the low frequency filter 332 that protects the power line 331, thereby suppressing to the utmost the variation of power supplied to the lamp heater 310. In the meantime, the low frequency filter 332 may be disposed in a region between the plasma generating unit 500 and the power line 331.

In another embodiment, the high frequency may affect the operation of the lamp heater 310. Therefore, it is more effective to wrap the lamp heater 310 with the light penetrating low frequency filter. The low frequency filter may be formed in a valve shape and selectively disposed at the lamp heater 310 and the base plate 120 of the chamber 100 only when the plasma is supplied by the high frequency.

The second heating unit 400 is disposed over the chamber 100 and supplies heat energy to the chamber 100. It is effective to use a belljar structure for the second heating unit 400. In this embodiment, an electrical heat source is used as the second heating unit 400, but it is not limited thereto. An optical heat source may be used as the second heat unit 400.

By disposing the heat source over the chamber 100, it is possible to uniformly heat the inside of the chamber 100 and to prevent heat from being lost through the upper portion of the chamber 100. The second heating unit 400 may be disposed over the substrate 10 to directly supply heat energy to the substrate 10. By providing heat to the substrate 10 using the second heating unit 400 that has the electrical heat source, it is possible to prevent the substrate 10 from being damaged by rapid heat variation, wherein a temperature of the heat provided to the substrate 10 is not rapidly changed. Herein, the electrical heat source may include a resistive heating source.

Referring to FIG. 3, the second heating unit 400 includes an inner safety plate 410, an outer cover 420, a center plate 430 disposed between the inner safety plate 410 and the outer cover 420, a cooling line 440 disposed between the outer cover 420 and the center plate 430, and a hot wire 450 disposed between the center plate 430 and the inner safety plate 410.

The inner safety plate 410 is formed in a cup shape and covers the top plate 130. That is, the inner safety plate 410 is made in the form of a rectangular box whose bottom is opened. It is effective to provide reflective coating on the bottom of the inner safety plate 410, i.e., a side corresponding to the top plate 130 of the chamber 100. Therefore, the radiant energy transmitted through the top plate 130 of the chamber 100 is reflected by the reflective coating and retransmitted to the reaction space of the chamber 100. As a result, the loss of the radiant energy can be reduced. In this embodiment, the hot wire 450 is disposed along a circumference of the inner safety plate 410. That is, the hot wire 450 is uniformly disposed in a space between the inner safety plate 410 and the center plate 430. Thus, the inner safety plate 410 is heated by the hot wire 450 and the heat of the inner safety plate 410 is transmitted to the top plate 130 of the chamber 100 to thereby heat the upper portion of the chamber 100. Therefore, it is preferable to form the inner safety plate 410 with a material having excellent heat conductivity. Although it is not shown, the second heating unit 400 may further include an energy supply sector for providing electrical energy to the hot wire 450.

The center plate 430 is disposed at the outside of the hot wire 450. Herein, the center plate 430 covers the hot wire 450 to prevent the heat from running out to the outside. For this purpose, the center plate 430 may further include a heat insulator therein, but it is not limited thereto. A heat insulator may be used as the center plate 430. As a result, it is possible to prevent the heat of the hot wire 450 from being run out toward an upper portion of the second heating unit 400.

The cooling line 440 is disposed on the center plate 430 having a function of heat insulation to cool an upper portion of the center plate 430 and to prevent the heat having a high temperature from being run out and thus damaging external equipments. The cooling line 440 may be disposed within the center plate 430.

The outer cover 420 protects the cooling line 440 by covering the cooing line 440.

In this embodiment, the hot wire 450 is disposed on an upper wall and a sidewall of the inner safety plate 410 having a rectangular box shape, but it is not limited thereto. The hot wire 450 may be locally disposed on the upper wall or the sidewall of the inner safety plate 410. Furthermore, the inner safety plate 410 is divided into a plurality of regions and a plurality of hot wires independently operating with each other may be disposed in a corresponding one of the plurality of regions of the inner safety plate 410. As a result, it is possible to locally adjust the temperature of the upper portion of the chamber 100 and thus to enhance the heating efficiency.

This embodiment includes the plasma generating unit 500 for the plasma generation in the reaction space of the chamber 100.

Therefore, the semiconductor device manufacturing apparatus can simultaneously perform a process for the high temperature processing and a process using the plasma. That is, in order to manufacture the semiconductor device, the heat energy of the first heating unit 300 is used as a first energy source; the heat energy of the second heating unit 400 is used as a second energy source; and the plasma of the plasma generating unit 500 is used as a third energy source. As described above, the semiconductor device manufacturing apparatus in accordance with this embodiment fabricates semiconductor films and devices using various energy sources.

In this embodiment, the native oxide layer on the substrate is removed using plasma energy and then a thin film is formed on the substrate where the native oxide layer is removed using two heat energy sources. The conventional apparatus removes the native oxide layer by performing a baking process using a H₂ gas at a high temperature greater than approximately 900° C. as described above. In this case, heat burden occurs. However, when performing the H₂ baking process at a temperature lower than approximately 800° C. in order to solve the above problem, a process time may be increased. In this embodiment, it is possible to remove the native oxide layer at a temperature lower than approximately 700° C. by performing a cleaning, i.e., etch, process using the plasma energy and thus to reduce a cleaning time. The plasma energy may be used in a process of depositing a thin film as well as the cleaning process.

The plasma generating apparatus 500 is able to generate plasma using various techniques including a capacitively coupled plasma (CCP) and an inductively coupled plasma (ICP). This embodiment will be described with respect to the ICP. In accordance with this embodiment, the damage due to the plasma can be prevented when using the ICP than the other techniques, e.g., the CCP. In case of the CCP, the chamber 100 can be damaged by a bombardment of ions since a sheath voltage is increased in a direction of the top plate 130 of the chamber 100 through which radio frequency (RF) power is supplied. Therefore, this embodiment adopts the ICP whose ion damage is less than that of the CCP.

Referring to FIG. 3, the plasma generating unit 500 includes an antenna 510 and a high frequency power sector 520 for supplying high frequency power to the antenna 510.

The antenna 510 is disposed over the top plate 130 of the chamber 100. As illustrated in FIG. 3, when the top plate 130 has a domy shape, it is effective to dispose the antenna 510 at the edge of the dome, i.e., a region adjacent to the chamber body 110. Referring to FIG. 3, the antenna 510 is formed to wrap the top plate 130 twice, but it is not limited thereto. The antenna 510 may wrap the top plate 130 more than 2 times or less than 2 times.

Herein, the antenna 510 may use a coil and a plurality of coils may be connected in series or in parallel. The coil uses a tube type member formed of copper or a conductive metal. Moreover, in order to effectively use high frequency RF power, a surface of the coil may be coated with a material having high electrical conductivity such as silver. In addition, in order to prevent the coil from being oxidized, an anti-oxidizing coating process such as Ni coating may be performed on the surface of the coil. The antenna 510 may be readily damaged by heat having a high temperature generated by the first and the second heating units 300 and 400. Therefore, a rise in temperature of the coil may be suppressed by forming within the coil a path through which cooling fluid flows.

The high frequency power sector 520 provides a high frequency to the antenna 510 to generate plasma in the reaction space of the chamber 100. Herein, the high frequency power sector 520 uses high frequency RF power in a range of approximately 100 kHz to approximately 100 MHz. Of course, the high frequency power sector 520 may use RF power of approximately 13.56 MHz having a tolerance of 10%. The high frequency RF power can be changed according to the size of the substrate 10 in the chamber 100. For instance, it is effective to use RF power in a range of approximately 500 W to approximately 1000W with respect to the substrate 10 being 200 mm in diameter. Herein, the high frequency power sector 520 continuously provides the high frequency RF power for a certain period to the antenna 520, but it is not limited thereto. The high frequency RF power may be provided for the certain period regularly or irregularly according to needs.

A portion of the high frequency power sector 520 penetrates the second heating unit 400 and is connected to the antenna 510 disposed in a space between the second heating unit 400 and the chamber 100. For this purpose, the second heating unit 400 includes at its upper portion a given penetrating groove 460 where an electric wire of the high frequency power sector 520 penetrates. Herein, it is effective to use a penetrating groove whose inside is filled with a heat insulating material to prevent heat loss.

The chamber 100 is grounded. The substrate disposing unit 200 is grounded through a separate means. If high frequency power having a value greater than a given level is supplied to the antenna 510 through the high frequency power sector 520, plasma is generated within the chamber 100. The plasma may have various types according to a kind of an inner gas and the pressure in the reaction space of the chamber 100.

Herein, it is effective to maintain a distance between the antenna 510 and the metal parts of the second heating unit 400 to be greater than a distance the antenna 510 and a region where the plasma is generated. As a result, it is possible to prevent induced electric fields from being generated between the antenna 510 and the metal parts and thus to prevent arching and power loss.

The plasma generating unit 500 is not limited to the above description and may have various modifications thereof. In the semiconductor device manufacturing apparatus in accordance with this embodiment, the chamber 100 is heated up to a high temperature by the first and the second heating units 300 and 400 disposed under and over the chamber 100, respectively. Therefore, the antenna 510 of the plasma generating unit 500, disposed in a region adjacent to the top plate 130 of the chamber, may be readily deformed or damaged by the heat. Thus, it is preferable to insulate the antenna 510 from the heat.

Referring to FIGS. 4A and 4B, a shielding plate 610 is disposed in a region between the top plate 130 of the chamber 100 and the antenna 510, wherein the shielding plate 610 shields radiant heat transmitted through the top plate 130 of the chamber 100. As shown in FIG. 4A, the shielding plate 610 may be formed in a single plate type corresponding to all of the antennas 510 wrapping the top plate 130 several times. Referring to FIG. 4B, the shield plate 610 may be formed to separately shield each of the antennas 510. As a result, it is possible to reduce the heat energy directly supplied to the antenna 510 by shielding the radiant heat from the first heating unit 300.

Referring to FIG. 5, the shielding plate 610 is disposed on a surface of a portion of the top plate 130 that is adjacent to the antenna 510, thereby shielding the radiant heat.

Referring to FIGS. 6A and 6B, the shielding plate 610 is formed as a portion of the top plate 130 which is adjacent to the antenna 510, thereby shielding the radiant heat directly supplied to the antenna 510, wherein the shielding plate 610 illustrated in FIGS. 6A and 6B is formed of a material capable of shielding the radiant heat. For this purpose, the top plate 130 is divided into a central region and an edge region. Then, preferably, the edge region corresponding to the antenna 510 is formed of the material capable of shielding the radiant heat and the central region is formed of a light penetrating material. As shown in FIG. 6, the edge region of the top plate 130 may have certain grooves where the antennas 510 are disposed.

Ceramic may be used as the material for shielding the radiant heat used in the modifications of the first embodiments, but it is not limited thereto. The radiant heat shielding material may include an insulating material having low light permeability. That is, it is effective to use a light non-penetrating material such as non-transparent quartz or opaque quartz.

The present invention is not limited to the embodiments described above. Hereinafter, another embodiment of the present invention will be described with reference to related drawings. A description of an overlap between embodiments to be described hereinafter and the above-described embodiments will be omitted for the simplicity of explanation. The technology relating to the following embodiments is also applicable to the above-described embodiments.

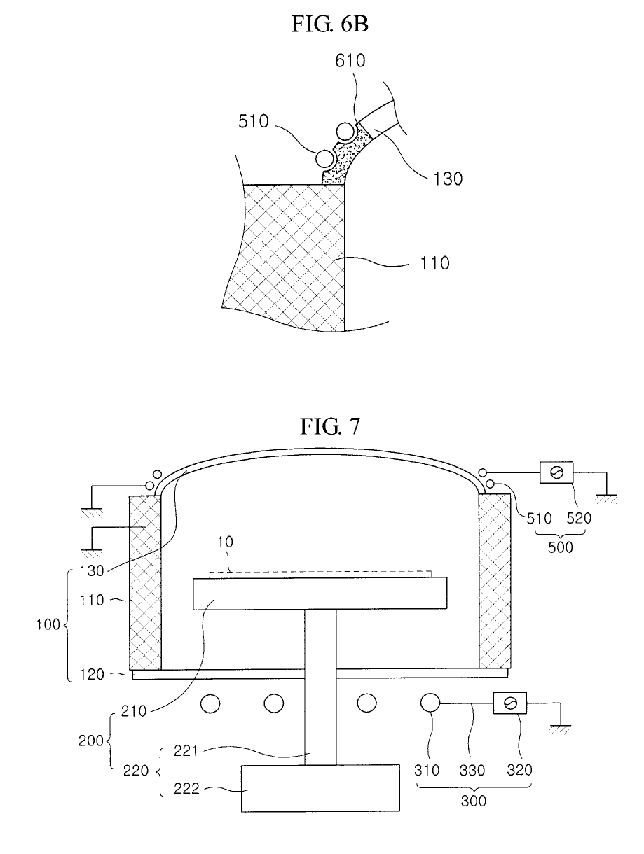

FIG. 7 illustrates a cross-sectional view of a semiconductor device manufacturing apparatus in accordance with a second embodiment of the present invention.

Referring to FIG. 7, the semiconductor device manufacturing apparatus includes a chamber 100, a substrate disposing unit 200, a first heating unit 300 and a plasma generating unit 500. That is, this embodiment does not include a second heating unit 300.

It is effective to use a top plate 130 of the chamber 100 that is formed with a light non-penetrating material and includes a reflective film coated on its inner surface. As a result, radiant heat of the first heating unit 300 can be reflected by the reflective film and thus transmitted again to a reaction space of the chamber 100 without being emitted to the outside through the top plate 130. The top plate 130 and a base plate 120 of the chamber 100 may be formed in a domy shape to enhance heat balance.

An antenna 510 of the plasma generating unit 500 is disposed near an edge region of the top plate 130. Herein, the antenna 510 can be thermally stabilized since the top plate 130 shields the antenna 510 from radiant heat in the chamber 100.

The present invention is not limited to the embodiments described above. Hereinafter, still another embodiment of the present invention will be described with reference to related drawings. A description of an overlap between embodiments to be described hereinafter and the above-described embodiments will be omitted for the simplicity of explanation. The technology relating to the following embodiments is also applicable to the above-described embodiments.

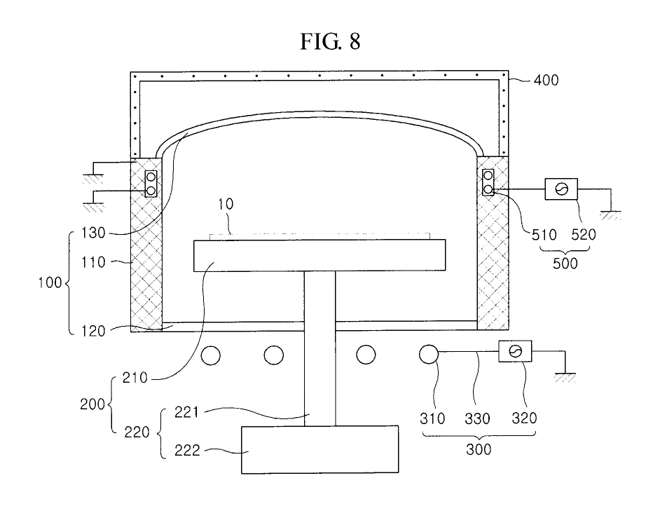

FIG. 8 illustrates a cross-sectional view of a semiconductor device manufacturing apparatus in accordance with a third embodiment of the present invention.

Referring to FIG. 8, the semiconductor device manufacturing apparatus includes a chamber 100, a substrate disposing unit 200, a first and a second heating unit 300 and 400 and a plasma generating unit 500 including an antenna 510 disposed within the chamber 100.

The plasma generating unit 500 includes the antenna 510 disposed within a chamber body 110 of the chamber 100 and a high frequency power sector 520 connected to the antenna 510 to supply high frequency power to the antenna 510.

The chamber body 110 includes a hollow inner space at its upper portion. The hollow space is formed to have a circular band shape along a circumference of the chamber body 110, but it is not limited thereto. A portion of the chamber body 110 may be formed as a concave groove caving in from the outside to the inside. The antenna 510 is disposed in the inner space and on the concave groove of the chamber body 110. As a result, it is possible to prevent radiant heat of the first heating unit 300 from being directly transmitted to the antenna 510 by changing the location of the antenna 510, and to prevent the antenna 510 from being thermally deformed by separating the second heating unit 400 from the antenna 510 in a certain distance. Although it is not shown, there may be formed a cooling fluid path in a region of the chamber body 110 which is adjacent to the antenna 510, thereby cooling a portion of the chamber body 110 where the antenna 510 is disposed, so that the thermal deformation of the antenna 510 can be prevented. Herein, a portion or all of the chamber body 110 may be formed of an insulating material.

Various semiconductor films may be formed using the above-described semiconductor device manufacturing apparatuses.

Hereinafter, a method of forming a semiconductor film will be described.

First of all, a temperature of the chamber 100 is maintained to an etch temperature for the plasma etch using the first and the second heating units 300 and 400. Then, the substrate 10 is disposed on the substrate disposing unit 200 in the chamber 100. Herein, the chamber 100 may be heated up after the substrate 10 is disposed on the substrate disposing unit 200. The plasma generating unit 500 generates plasma within the reaction space of the chamber 100 and then an etch gas is injected into the reaction space, thereby removing the native oxide layer on a surface of the substrate 10. After removing the native oxide layer, the plasma generation is stopped, and the first and the second heating units 300 and 400 re-heat the chamber 100 up to a temperature for the deposition of the semiconductor film. Subsequently, a semiconductor deposition gas and the etch gas are alternately injected into the chamber 100 to thereby deposit the semiconductor film. If it is required, the semiconductor film may be formed only using the semiconductor deposition gas. After the semiconductor film is deposited, the chamber 100 is cooled down and then the substrate 10 is unloaded to the outside of the chamber 100.

The method of forming the semiconductor film will be explained in detail hereinafter.

The inside of the chamber 100 is heated up using the first and the second heating units 300 and 400. It is effective to maintain a temperature of the second heating unit 400 in a range of approximately 200° C. to approximately 600° C. That is, the temperature of the second heating unit 400 is fixed. In this embodiment, it is preferable that the temperature of the second heating unit 400 is fixed in a range of approximately 450° C. to approximately 550° C. By maintaining the temperature of the second heating unit 400 in the above range, it is possible to prevent the significant variation of heat energy directly provided to the substrate 10. It is preferable to maintain the temperature of the chamber 100 in a range in which the oxide layer can be etched using the first heating unit 300. It is effective to keep the temperature for the oxide etching in a range of approximately 200° C. to approximately 600° C. It is possible to inactivate the second heating unit 400. By adjusting the oxide etch temperature to the above range, etch efficiency can be optimized and it is possible to reduce excessive thermal burden given to the substrate 10.

Then, the substrate 10 is disposed on the substrate disposing unit 200 in the chamber 100. There is generated plasma using the plasma generating unit 500 while injecting a gas for etching oxide to the reaction space, so that the oxide etch gas is changed to a plasma state. The native oxide layer and impurities on the surface of the substrate 10 are removed by the oxide etch gas in the plasma state. The oxide etch gas may include a F-based and/or Cl-based gas such as Cl₂, HCl, ClF₃ or SF₆. By etching a portion of the surface of the substrate 10 through the etch process using the plasma, a combining property of a thin film to be formed can be enhanced.

After removing the native oxide layer on the surface of the substrate 10, the plasma generation is stopped; the injection of the oxide etch gas is blocked; and the chamber 100 exhausts. Then, the first heating unit 300 is heated up to a deposition temperature having a level greater than that of the oxide etch temperature. It is effective to keep the deposition temperature in a range of approximately 300° C. to approximately 1000° C. In case that the second heating unit 400 is inactivated, the second heating unit 400 may be activated while the temperature of the first heating unit 300 is rising. At this time, it is possible to maintain the temperature of the second heating unit 400 activated in a range of approximately 200° C. to approximately 600° C.

Then, a silicon source gas is provided to deposit a silicon epitaxial layer. The silicon source gas may include SiH₄, Si₂H₆, or DCS. If there is required selectivity where an oxide layer or a nitride layer is not deposited, the silicon epitaxial layer may be deposited by alternately supplying the silicon source gas and the etch gas. In the meantime, the silicon epitaxial layer may be deposited by simultaneously supplying the silicon source gas and the etch gas.

After the deposition of the silicon epitaxial layer is completed, the temperature of the first heating unit 300 is lowered to a range of approximately 200° C. to approximately 600° C. Then, the substrate 10 disposed on the substrate disposing unit 200 is unloaded to the outside of the chamber 100.

In accordance with this embodiment, the process of removing the native oxide layer on the surface of the substrate using the plasma and the process of forming the semiconductor film on the substrate can be performed in one single chamber.

In the above description, the plasma generating unit is only used in the process of removing the native oxide layer on the surface of the substrate, but it is not limited thereto. The plasma generating unit can be used in the process of depositing the semiconductor film. Therefore, the thin film can be deposited at a temperature under a range of approximately 10% to approximately 50% of set temperatures of the first and the second heating units. This means that it is able to reduce the heating temperature of the lamp heater of the first heating unit.

Firstly, the temperature of the chamber 100 is maintained to a temperature for plasma etching by the first and the second heating units 300 and 400. Then, the substrate 10 is disposed on the substrate disposing unit 200 in the chamber 100. Meanwhile, the chamber 100 may be heated up after the substrate 10 is disposed. Subsequently, the plasma generating unit 500 generates plasma within the reaction space of the chamber 100 and then the etch gas is injected into the reaction space, thereby removing the native oxide layer on the surface of the substrate 10. After removing the native oxide layer, the plasma generation is stopped, and the first and the second heating units 300 and 400 re-heat the chamber 100 up to a temperature for the deposition of the semiconductor film. Subsequently, a semiconductor deposition gas and the etch gas are alternately injected into the chamber 100 to thereby deposit the semiconductor film. If it is required, the semiconductor film may be formed only using the semiconductor deposition gas. After the semiconductor film is deposited, the chamber 100 is cooled down and then the substrate 10 is unloaded to the outside of the chamber 100.

In addition, in a method of depositing a thin film using the apparatus in accordance with the embodiment of the present invention, the plasma is generated in the chamber 100 when depositing the thin film.

That is, the substrate 10 is disposed on the substrate disposing unit 200 in the chamber 100. Then, the chamber 100 is heated up to a first temperature by the first heating unit 300 and/or the second heating unit 400. The first temperature is a process temperature at which the native oxide layer on the surface of the substrate 10 is removed by the plasma.

Then, the plasma is generated in the reaction space of the chamber 100 through the plasma generating unit 500. A first gas for the cleaning is injected into the chamber 100 to thereby remove the native oxide layer on the surface of the substrate 10.

Subsequently, the plasma generation is stopped and an unreacted first gas exhausts. The chamber 100 is heated up to a second temperature through the first and the second heating units 300 and 400. The second temperature is a temperature at which the thin film is deposited on the surface of the substrate 10 using the plasma and is preferable greater than the first temperature. Then, there is generated the plasma again in the reaction space of the chamber 100 and the deposition process is performed to deposit the thin film on the surface of the substrate 10. In the deposition process, the thin film is formed on the surface of the substrate 10 by alternately supplying the deposition gas and the etch gas to the reaction space of the chamber 100. At this time, the reactivity of the deposition gas and the etch gas is improved by the plasma generated in the reaction space and thus it is possible to reduce a time required for forming the semiconductor thin film and to improve the quality of the thin film.

Meanwhile, the plasma can be generated during at least one of the deposition gas and the etch gas being supplied. For instance, the plasma may be generated during the deposition gas being supplied and the generation of the plasma may be stopped during the etch gas being supplied. As a result, the reactivity of the deposition gas may be improved.

Although the above description is focused on the process of removing the native oxide layer on the surface of the substrate, it is not limited thereto and the inventive apparatus may be used in a process of removing a nitride layer.

As described above, since the inventive apparatus includes the optical heating unit disposed under the chamber and the electrical heating unit disposed over the chamber, the inside of the chamber can be uniformly heated.

Furthermore, since the inventive apparatus generates the plasma using the plasma generating unit disposed over the chamber, the deposition process based on heating and the etch process based on the plasma can be simultaneously performed in one single chamber.

In accordance with the present invention, by employing the low frequency filter and the radiant heat shielding plate, it is possible to minimize the interference between the lamp heater of the optical heating unit and the antenna of the plasma generating unit.

Although the present invention has been described in connection with the exemplary embodiments of the present invention, it will be apparent to those skilled in the art that various modifications and changes may be made thereto without departing from the scope and spirit of the invention.

What is claimed is:

1. An apparatus for manufacturing a semiconductor device, the apparatus comprising:
a chamber including a reaction space;
a substrate disposing unit configured to dispose a substrate within the chamber;
a first heating unit configured to optically heat the reaction space and disposed under the chamber;
a second heating unit configured to heat the reaction space through resistive heating and disposed over the chamber; and
a plasma generating unit configured to generate plasma in the reaction space.

2. The apparatus of claim 1, wherein the first heating unit comprises a lamp heater and the second heating unit comprises a hot wire.

3. The apparatus of claim 2, wherein the lamp heater comprises a power supply sector configured to supply power and a power supply line electrically connecting the power supply sector and the lamp heater, and further comprises a low frequency filter disposed between the power supply line and the plasma generating unit.

4. The apparatus of claim 1, wherein the chamber comprises a chamber body, a light penetrating base plate disposed at a lower portion of the chamber body and a top plate disposed at an upper portion of the chamber body, and the plasma generating unit comprises at least one antenna disposed in a region between the second heating unit and the top plate of the chamber and a high frequency power sector configured to provide high frequency power to the antenna, wherein the top plate has a light penetrating part and a light non-penetrating part and the non-penetrating part is formed in a region of the top plate corresponding to the antenna.

5. The apparatus of claim 1, wherein the chamber comprises a chamber body having an inner space therein or a concave groove caving in from the outside to the inside, a light penetrating base plate disposed at a lower portion of the chamber body and a top plate disposed at an upper portion of the chamber body, and the plasma generating unit includes at least one antenna disposed in the inner space or the concave groove and a high frequency power sector configured to provide high frequency power to the antenna.

6. A method of manufacturing a semiconductor device using a semiconductor device manufacturing apparatus that includes a chamber having a substrate disposing unit on which a substrate is disposed, a first and a second heating unit disposed under and over the chamber, respectively, and a plasma generating unit disposed at an upper portion of the chamber, the method comprising:
heating up a reaction space of the chamber to a first temperature using at least one of the first and the second heating units;
cleaning a surface of the substrate using plasma and a cleaning gas;
heating up the reaction space of the chamber to a second temperature using the first and the second heating units, wherein the second temperature is higher than the first temperature;
depositing a semiconductor film on the substrate using a deposition gas and an etch gas;
stopping the supply of the deposition gas and the etch gas and cooling down the chamber; and
unloading the substrate to the outside of the chamber.

7. The method of claim 6, wherein the first temperature is a process temperature at which a native oxide layer on the surface of the substrate is removed using the plasma and is in a range of approximately 200° C. to approximately 600° C., and the second temperature is a process temperature at which the thin film is deposited and is in a range of approximately 300° C. to approximately 1000° C.

8. The method of claim 6, wherein cleaning the surface of the substrate comprises:
generating the plasma in the reaction space using the plasma generating unit after injecting the cleaning gas to the reaction space of the chamber, or injecting the cleaning gas to the reaction space after generating the plasma in the reaction space; and
stopping the generation of the plasma and the injection of the cleaning gas.

9. The method of claim 8, wherein the plasma is generated by supplying high frequency power to an antenna that is disposed over the chamber in the form of wrapping the chamber.

10. The method of claim 6, wherein, when depositing the semiconductor film on the substrate, the deposition gas for the deposition of the semiconductor film and the etch gas for the etching of the semiconductor film are alternately supplied to the reaction space of the chamber, or the deposition gas and the etch gas are simultaneously supplied to the reaction space.

11. The method of claim 10, wherein the plasma is generated in the reaction space using the plasma generating unit during at least one of the deposition gas and the etch gas being supplied.

12. The method of claim 6, wherein a temperature of the reaction space of the chamber is changed by varying a temperature of the first heating unit while fixing a temperature of the second heating unit.
